(19) United States
(12) Patent Application Publication
(10) Pub. No.: US 2026/0290640 A1
(43) Pub. Date: Sep. 24, 2026

(54) HYDRIDE-BASED SUPERCONDUCTORS

(71) Applicant: Deep Science, LLC, Bellevue, WA (US)

(72) Inventors: Brian Charles Holloway, Snoqualmie, WA (US); Rohit P. Prasankumar, Albuquerque, NM (US); Christopher James Pickard, Cambridge (GB); Kapildeb Dolui, London (GB)

(21) Appl. No.: 19/037,230

(22) Filed: Jan. 26, 2025

Related U.S. Application Data
(63) Continuation of application No. PCT/US2023/071039, filed on Jul. 26, 2023.
(60) Provisional application No. 63/369,484, filed on Jul. 26, 2022.
(60) Provisional application No. 63/486,447, filed on Feb. 22, 2023.
(60) Provisional application No. 63/491,338, filed on Mar. 21, 2023.

(51) Int. Cl. H01B 1/06; H01B 12/16

(52) U.S. Cl. CPC H01B 1/06; H01B 12/16

(57) ABSTRACT

According to various embodiments, a hydride superconducting material includes at least one binary, ternary, or quaternary hydride selected from a group of hydrides consisting of: αH₄, βH₃, γH₆, δH₁₀, αβHₓ, or αβγHₓ, wherein each of α, β, γ, and δ is an element in the periodic table, and x represents an integer number of hydrogen atoms.

If an Application Data Sheet (ADS) has been filed on the filing date of this application, it is incorporated by reference herein. Any applications claimed on the ADS for priority under 35 U.S.C. § § 119, 120, 121, or 365(c), and any and all parent, grandparent, great-grandparent, etc. applications of such applications are also incorporated by reference, including any priority claims made in those applications and any material incorporated by reference, to the extent such subject matter is not inconsistent herewith.

### CROSS-REFERENCE TO RELATED APPLICATIONS

The present application claims the benefit of the earliest available effective filing date(s) from the following listed application(s) (the “Priority Applications”), if any, listed below (e.g., claims earliest available priority dates for other than provisional patent applications or claims benefits under 35 U.S.C. § 119(e) for provisional patent applications, for any and all parent, grandparent, great-grandparent, etc. applications of the Priority Application(s)). In addition, the present application is related to the “Related Applications,” if any, listed below.

### Priority Applications

This application claims priority to and is a continuation of PCT Patent Application No. PCT/US2023/071039 titled HYDRIDE-BASED SUPERCONDUCTORS, filed on Jul. 26, 2023, which claims benefit under 35 U.S.C. 119 and priority to: U.S. Provisional Patent Application No. 63,369,484 titled “Hydride-Based Superconductors,” filed on Jul. 26, 2022; U.S. Provisional Patent Application No. 63,486,447 titled “Hydride-Based Superconductors,” filed on Feb. 22, 2023; and U.S. Provisional Patent Application No. 63,491,338 titled “Hydride-Based Superconductors,” filed on Mar. 21, 2023. Each of the four applications identified above is hereby incorporated by reference in its entirety.

### Related Applications

If the listings of applications provided above are inconsistent with the listings provided via an ADS, it is the intent of the Applicant to claim priority to each application that appears in the Priority Applications section of the ADS and to each application that appears in the Priority Applications section of this application.

All subject matter of the Priority Applications and the Related Applications and of any and all parent, grandparent, great-grandparent, etc. applications of the Priority Applications and the Related Applications, including any priority claims, is incorporated herein by reference to the extent such subject matter is not inconsistent herewith.

### TECHNICAL FIELD

This disclosure relates to superconductors. This disclosure particularly relates to hydrogen-based superconductors (hydrides) and methods of making hydride-based superconductors.

### BRIEF DESCRIPTION OF THE DRAWINGS

FIG. 1A illustrates an atomic configuration of a silane or silicon hydride (SiH₄) superconductor material, according to one embodiment.

FIG. 1B illustrates an atomic configuration of an αH₄ superconductor material, where α is an element selected from the periodic table, according to one embodiment.

FIG. 2 illustrates an atomic configuration of an aluminum hydride (AlH₃) superconductor material, according to one embodiment.

FIG. 3 illustrates an atomic configuration of a sulfur hydride (H₃S) superconductor material, according to one embodiment.

FIG. 4 illustrates an atomic configuration of a calcium hydride (CaH₆) superconductor material, according to one embodiment.

FIG. 5 illustrates an atomic configuration of a lanthanum decahydride (LaH₁₀) superconductor material, according to one embodiment.

FIGS. 6A and 6B illustrate atomic configurations of an example ternary hydride, KB₂H₈, according to one embodiment.

FIGS. 7A and 7B illustrate atomic configurations of another example ternary hydride, CsBH₅, according to one embodiment.

FIGS. 8A and 8B illustrate atomic configurations of an example of a quaternary hydride, H₁₂ScY₂La, as balls and sticks and as polyhedrons of hydrogen atoms, respectively, according to one embodiment.

FIGS. 9A and 9B illustrate example atomic configurations of a ternary hydride of the form α₂βH₆, specifically illustrating Mg₂IrH₆, as balls and sticks and as polyhedrons of hydrogen atoms, respectively, according to one embodiment.

FIG. 10 illustrates an example atomic configuration of a ternary hydride of the form α₂βH₇, specifically illustrating Mg₂IrH₇, according to one embodiment.

FIG. 11 illustrates a hydride superconducting device cooled by a cooling system, according to one embodiment.

FIG. 12 illustrates a hydride superconducting material on a substrate that is cooled by a cooling system, according to one embodiment.

FIG. 13 illustrates a hydride superconducting superlattice on an optional substrate that is cooled by a cooling system, according to one embodiment.

### DETAILED DESCRIPTION

This disclosure includes a description of various hydrogen-based superconductors (hydrides) that exhibit superconductivity at relatively high temperatures. The temperature at or below which the hydride exhibits superconductivity is referred to as the critical temperature (T_{c}). Accordingly, at temperatures at or below the critical temperature, the hydrides become superconducting (e.g., have zero electrical resistance and expel magnetic fields). When not stated otherwise, the critical temperature of a superconducting material is usually described in the context of a known pressure for a particular type of superconducting material and/or at standard pressure (approximately 101.325 kilopascals).

Some of the described hydrides exhibit superconductivity at critical temperatures above 200 Kelvin and, in some instances, at or above 293 Kelvin with applied pressures exceeding 100 gigapascals. Some of the presently described hydride superconductor materials have critical temperatures exceeding 200 Kelvin at much lower pressures (e.g., less than 20 gigapascals). Various examples of this disclosure include systems and devices for use in superconducting motors, wires, interconnects, and magnets. Some of the examples described herein include relatively low-pressure hydride superconductors operating at temperatures above 200 Kelvin and pressures below 20 gigapascals.

According to various embodiments, a system or superconducting device may include a superconducting material, a cooling system, and a controller. The superconducting material may, for example, be maintained within a cryocooler. The controller, in connection with the cooling system, may maintain the superconducting material at or below the critical temperatures and/or at or above a target pressure associated with the critical temperature of the superconducting material. Just as the temperature at or below which a material exhibits superconductivity is referred to as the critical temperature, the pressure above which the temperature exhibits superconductivity can be referred to as a critical pressure (P_{c}). Some superconductor materials may exhibit superconductivity at different critical temperatures depending on the applied pressure and different critical pressures depending on the temperature.

According to various aspects of this disclosure, a superconducting material comprises a hydride that is fabricated, configured, doped, or otherwise modified as described herein to increase the critical temperature at which the hydride exhibits superconductivity and/or lower the pressure required for superconductivity at a given temperature, relative to a bulk form of the same hydride. Examples of hydride structures that can be used to form superconducting materials include, without limitation, one or more of the binary hydrides having the form of αH₄, βH₃, γH₆, δH₁₀, and εH₉ wherein each of α, β, γ, δ, and ε represents an element in the periodic table or a chemical functional group (e.g., NH₄, CH₄, etc.). In some instances, α, β, γ, δ, and ε may be five different elements (or chemical functional groups. In other instances, some or all α, β, γ, δ, and ε may be the same element. Some specific examples of binary hydrides include, for example, and without limitation, SiH₄, AlH₃, H₃S, CaH₆, LaH₁₀, YH₉, AuH₄, PtH₄, and AgH₄.

In other embodiments, examples of ternary hydride structures that can be used to form superconducting materials include, without limitation, one or more hydrides having the form of αβHₓ, where α represents a first element in the periodic table, β represents a different element in the periodic table, H represents hydrogen atoms, and the subscript “x” is an integer such that Hₓ represents the number of hydrogen atoms in the ternary hydride. As previously described, in some embodiments, the terms α and β may represent chemical functional groups instead of individual elements. In some embodiments, one or more ternary hydride structures may be used that take the form of α_{y}β_{z}Hₓ, where α represents a first element in the periodic table, β represents a different element in the periodic table, H represents hydrogen, and the subscripts “y,” “z,” and “x” are each an integer, such that α_{y} represents the number of atoms of the first element in the ternary hydride, β_{z} represents the number of atoms of the second element in the ternary hydride, and Hₓ represents the number of hydrogen atoms in the ternary hydride. In some examples, ternary hydrides that can be used to form superconducting materials take the form of α₂βH₆ or α₂βH₇, as described herein. Throughout this disclosure the subscripts for the α, β, and γ representing different elements and/or chemical functional groups are implied but omitted for clarity and brevity. Thus, the expression α_{y}β_{z}Hₓ is equal to αβHₓ through this disclosure, unless explicitly stated otherwise or contextually required.

Additionally, superconducting materials may be formed using quaternary (or higher) hydride structures. In some instances, the use of quaternary and higher hydride structures allows for the formation of superconducting devices and superconducting systems that operate at lower pressure (e.g., ambient pressure in some instances) and/or higher superconducting critical temperatures (T_{c}).

According to various embodiments, quaternary hydride structures take the form of αβγHₓ, where α represents a first element in the periodic table (or chemical functional group), β represents a second element in the periodic table (or chemical functional group), γ represents a third element in the periodic table (or chemical functional group), and the subscript “x” represents the integer number of hydrogen atoms in the quaternary hydride. Throughout this disclosure, the use of α to represent the first element, β to represent the second element, and γ to represent the third element are used with the understanding by one of skill in the art with an applied subscript denoting the exact number of α, β, and γ atoms that are present relative to the x number of hydrogen atoms. By way of example, a quaternary hydride structure in the form of αβγHₓ encompasses but is not limited to, compositions such as αβC₆H₆, in which γ represents the six carbon atoms.

According to various embodiments, binary, ternary, quaternary, etc., hydride structures may be manufactured or synthesized at high pressures in, for example, a diamond anvil cell (DAC). Various techniques and approaches may be utilized to increase the stability of the hydride structure at lower pressures. In some examples, a hydride structure described herein may be synthesized during a pressure quenching process, where the pressure is lowered during synthesis at a pressure release rate to stabilize the phase of the hydride.

Examples of suitable synthesis processes are described in Chu et al., The Retention and Study of High-Pressure-Inducted Phases in High- and Room-Temperature Superconductors, Journal of Superconductivity and Novel Magnetism, v. 35, p. 987-995 (2022); Kuzovnikov et al. Synthesis of superconducting hcp-Zr-H₃ under high hydrogen pressure, Phys. Rev. Materials 7, 024803 (February 13, 2023); A. P. Drozdov et al., “Superconductivity at 250 K in lanthanum hydride under high pressures,” Nature 569, 528 (2019) and E. Snider et al., Synthesis of Yttrium Superhydride Superconductor with a Transition Temperature up to 262 K by Catalytic Hydrogenation at High Pressures, Phys. Rev. Lett. 126, 117003 (2021 ), each of which is hereby included by reference to the extent allowed by law and assumed to be understood by one of skill in the art in the context of the present disclosure of binary, ternary, and quaternary hydrides for superconducting devices.

The various examples of hydrides described herein may be synthesized at and/or exhibit superconductive properties at various temperatures and pressures as understood by those of skill in the art in the context of the publications listed below, which are hereby incorporated by reference to the extent allowed by law and understood by those of skill in the art: Xiao et al., Structure and superconductivity of protactinium hydrides under high pressure, J Phys Condens Matter. 31, 315403(2019 ); Peng et al., Metallization of hydrogen by intercalating ammonium ions in metal fcc lattices at lower pressure, Phys. Rev. Lett. 119, 107001 (2017 ); Liang et al., Prediction of high-T_{c} superconductivity in ternary lanthanum borohydrides, Phys. Rev. B 104, 134501 (2021 ); Gao et al., Phonon-mediated high-temperature superconductivity in the ternary borohydride KB₂H₈ under pressure near 12 GPa, Phys. Rev. B 104, L100504 (2021 ); Han et al., Clathrate-Like Alkali and Alkaline-Earth Metal Borides: A New Family of Superconductors with Superior Hardness, Advanced Functional Materials (2023) available at https://doi.org/10.1002/adfm.202213377; Ding et al., Ambient-pressure high-T_{c} superconductivity in doped boron-nitrogen clathrates La(BN)₅ and Y(BN)₅, Phys. Rev. B 106, 104508 (2022 ); Jiang et al., High-temperature superconductivity below 100 GPa in ternary C-based hydride MC2H8 with molecular crystal characteristics (M=Na, K, Mg, Al, and Ga), Phys. Rev. B 105, 104511 (2022 ); Li et al., Hard BN Clathrate Superconductors, The Journal of Physical Chemistry Letters 10, 2554-2560 (2019) available at 10.1021/acs.jpclett.9b00619; Jiang et al., Phonon-Mediated Low-Pressure Superconductivity in Ternary Hydride Ba—CH₄ ACS, Applied Electronic Materials 3, 4172-4179 (2021), available at 10.1021/acsaelm.1c00617; Li et al., Superconductivity in compressed ternary alkaline boron hydrides, Phys. Rev. B 105, 224107 (2022 ); Wan et al., Metallization of hydrogen by intercalating ammonium ions in metal fcc lattices at lower pressure, Appl. Phys. Lett. 121, 192601 (2022 ) available at https://doi.org/10.1063/5.0127365; Zhang et al. Design Principles for High-Temperature Superconductors with a Hydrogen-Based Alloy Backbone at Moderate Pressure Phys. Rev. Lett. 128, 047001 (2022 ); He et al., Phonon-Mediated High-Temperature Superconductivity in Few-Hydrogen Metal-Bonded Perovskite Al4H up to 54 K under Ambient Pressure, (January 2023) available at https://doi.org/10.48550/arXiv.2301.09032; Gao et al., Stabilizing hydrogen-rich superconductor around ambient pressure by charge transfer modulated virtual high-pressure effect, available at https://doi.org/10.48550/arXiv.2301.12320; Liu et al., Generic rules for achieving room-temperature superconductivity in ternary hydrides with clathrate structures, Phys. Rev. B 107, L020504 (January 2023); Koshoji et al., Prediction of quaternary hydrides based on densest ternary sphere packings, Phys. Rev. Materials 6, 114802 (2022); and Li et al., Transformation of hexagonal Lu to cubic LuH₂₊ₓ single-crystalline films, (April 17, 2023) available at https://arxiv.org/abs/2304.07966.

The illustrated hydrides or hydride structures are merely examples of suitable hydrides or hydride structures that can be used, fabricated, configured, and/or modified as described herein to form superconductive materials that exhibit superconductivity at relatively high temperatures and/or relatively low pressures as compared to the critical temperatures and pressures of the same material in bulk, unmodified form. Again, additional hydrides are contemplated and are not exhaustively listed in this disclosure. Some hydride structures may exhibit superconductivity at critical temperatures that are sufficiently high and critical pressures that are sufficiently low, even in their bulk form, for use in some superconducting applications.

Various fabrications, formations, and configurations of hydrides are described herein that modify the superconductivity characteristics of the hydride. Specifically, the fabrication techniques and configurations described herein operate to raise the critical temperature of the hydride at which the hydride exhibits superconductivity and/or reduce the critical pressure required for superconductivity at a given temperature, as compared to a bulk form of a given hydride.

For example, bulk or two-dimensional layers of a hydride may be doped with a dopant to increase the critical temperature thereof and/or to lower the critical pressure associated with a given temperature at which the hydride exhibits superconductivity. Examples of suitable dopants include but are not limited to, nitrogen (N), boron (B), carbon (C), potassium (K), and sodium (Na). Substitutional doping may be used to replace some atoms in a lattice structure with other atoms or molecules. For example, focused Ion beam deposition may be used, for example, to dope a bulk or two-dimensional hydride with potassium (K). In some embodiments, a hydride material described herein may be doped with an intercalated dopant and/or an interstitial dopant.

In some embodiments, a thin film of any of the hydrides described herein can be fabricated to be less than ten structural unit cells thick (e.g., three-unit cells thick or five-unit cells thick). The thin film hydride can have a higher critical temperature than a bulk form of the same hydride. Further, a monolayer (i.e., one-unit cell thick) of the hydride or a bilayer of the hydride (i.e., two-unit cells thick) can exhibit a higher critical temperature than a bulk form of the same hydride.

In some examples, superconducting devices and systems utilize bulk, thin films, and/or ribbons of doped or undoped binary, ternary, and/or quaternary hydrides taking the form of αHₓ, αβHₓ, or αβγHₓ where α represents a first element in the periodic table, β represents a second, different element in the periodic table, γ represents a third, different element in the periodic table, and the subscript “x” represents the number of hydrogen atoms in the hydride. Examples of some additional binary hydrides that may be used alone or in combination with other hydrides include, without limitation, PaH₈, LaH₉, and Al₄H. Examples of some suitable ternary and quaternary hydrides that may be used alone or in combination with other hydrides include, without limitation, LaBH₈, KB₂H₈, MgC₂H₈, Ba—(CH₄)₃, RbB₂H₈, CsB₂H₈, AlN₂H₈, GaN₂H₈, MgN₂H₈, LaBeH_{8,} BaSiH₈, SrSiH₈, K₂ReH₉, CsBH₅, H₁₂ScY₂Sr, H₁₂ScY₂La, H₁₂TiNi₃Ba, H₁₂ScY₂Ca, PoIrH₄, TeIrH₄, TlIrH₉, SrIrH₉, HgIrH₉, TlIrH₁₀, SrIrH₁₀, and HgIrH₁₀. In some embodiments, the superconductor material may include a thin film, two-dimensional layer, or ribbon of a cesium-based hydride (e.g., CeH₉ and CeH₁₀) and/or an ammonium-based hydride (e.g., M(NH₄)₂, where M can include Mg, Al, and Ga.

In some examples, a superconducting device utilizes a bulk, thin film, and/or ribbon of doped or undoped ternary hydrides of the form α₂βH₆ or the complementary compound with the form α₂βH₇, as described herein. Hydrides having the form α₂βH₆ include two atoms of a first element, α, one atom of a second element, β, and six hydrogen atoms. Similarly, hydrides having the form α₂βH₇ include two atoms of a first element, α, one atom of a second element, β, and seven hydrogen atoms.

Numerous ternary hydrides having the form α₂βH₆, or the complementary form α₂βH₇, can be operated as superconductors at relatively high critical temperatures, T_{C}, and sustainable pressures. In some instances, the metallicity of such ternary hydrides may be maintained or increased by doping the ternary hydride. In some embodiments, the critical temperature, T_{C}, metallicity, and/or stability of a ternary hydride may be increased by increasing the pressure at which the superconductor material is operated. In some embodiments, the critical temperature, T_{C}, metallicity, and/or stability of a ternary hydride may be increased by alloying the ternary hydride with other compounds and/or another one of the binary hydrides, ternary hydrides, or quaternary hydrides described herein.

Examples of ternary hydrides that may be utilized as a part of a superconducting structure include but are not limited to: Mg₂IrH₆, Mg₂PtH₆, Mg₂RhH₆, Al₂MnH₆, Al₂ReH₆, Na₂AgH₆, Ca₂AgH₆, Na₂ZnH₆, Na₂AuH₆, Sr₂AgH₆, BNa₂H₆, Na₂AlH₆, AgBa₂H₆, Na₂GaH₆, TcIn₂H₆, In₂ReH₆, Ca₂GaH₆, NaBa₂H₆, Ca₂CuH₆, Ca₂PdH₆, CuSr₂H₆, NiNb₂H₆, GaSr₂H₆, AgCs₂H₆, CuY₂H₆, Sr₂PdH₆, Lu₂IrH₆, Lu₂ReH₆, TcLu₂H₆, Rb₂AgH₆, K₂AuH₆.

Similarly, the complementary ternary hydrides having the form of α₂βH₇ may additionally, or alternatively, be used as a superconducting material in a superconducting system or device. Examples of such ternary hydrides include but are not limited to, Mg₂IrH₇, Mg₂PtH₇, Mg₂RhH₇, Al₂MnH₇, Al₂ReH₇, Na₂AgH₇, Ca₂AgH₇, Na₂ZnH₇, Na₂AuH₇, Sr₂AgH₇, BNa₂H₇, Na₂AlH₇, AgBa₂H₇, Na₂GaH₇, TcIn₂H₇, In₂ReH₇, Ca₂GaH₇, NaBa₂H₇, Ca₂CuH₇, Ca₂PdH₇, CuSr₂H₇, NiNb₂H₇, GaSr₂H₇, AgCs₂H₇, CuY₂H₇, Sr₂PdH₇, Lu₂IrH₇, Lu₂ReH₇, TcLu₂H₇, Rb₂AgH₇, K₂AuH₇.

The example ternary hydrides described above with forms α₂βH₆ and α₂βH₇ are metallic. The superconducting properties of various ternary hydrides with the forms α₂βH₆ and α₂βH₇ can be tuned by, for example, adjusting the hydrogen content, doping, and/or alloying one or more of the α and β elements. In some embodiments, superconductor devices may utilize ternary hydrides with forms α₂βH₆ and α₂βH₇ that were previously reported as being semiconductors by doping and/or alloying the semiconductor ternary hydride to make it sufficiently metallic for superconductivity. In some embodiments, unstable variants of ternary hydrides of the forms α₂βH₆ and α₂βH₇ may be utilized in conjunction with doping and/or alloying to improve stability at a given operational temperature and pressure.

In some examples, superconducting structures may include a combination of any of the hydrides described herein and a clathrate boride or other boron-containing structure. In still other embodiments, superconducting structures are contemplated that omit hydride structures and instead utilize a doped or undoped clathrate boride or other boron-containing structure in a bulk form, as a thin film, or as a one-dimensional structure. Examples of suitable clathrate borides include but are not limited to, MgB₇, KB₇, La(BN)₅, Y(BN)₅, Al₂(BN)₆, and Al(BN)₆.

In some embodiments, the critical temperature of the hydride is increased (or the critical pressure is lowered) by incorporating a plurality of hydride layers in a superlattice structure of thin layers with different compositions. For example, a superconductor system may include a superlattice of thin films of two or more of the hydrides, including two or more of any of the binary, ternary, quaternary, etc. hydrides described herein. In various embodiments, the superlattice of thin films of different types of hydrides exhibits superconductivity at temperatures greater than attainable using any one type of thin film hydride by itself for a given pressure and/or at pressures lower than attainable using any one type of thin film hydride by itself for a given temperature. In one example embodiment, a superconducting hydride superlattice structure includes a multilayered structure with layers of two-dimensional or thin films of hydrogen and metal atom with one or more other layers in between.

In some embodiments, a thin film (e.g., between two-and ten-unit cells thick) or a monolayer of a selected hydride is fabricated on a ferroelectric material and/or a magnetic material (e.g., ferromagnetic, antiferromagnetic, or ferrimagnetic) to increase the critical temperature of the hydride at a given pressure (or lower the required pressure for a given temperature) at which the hydride exhibits superconductivity.

In various embodiments, any one of the hydrides described herein can be integrated with a polymer or other organic material (e.g., a molecular crystal) to increase the critical temperature of the hydride at a given pressure (or lower the required pressure for a given temperature) at which the hydride exhibits superconductivity.

In various embodiments, any one of the hydrides described herein can be integrated within a zero-dimensional, one-dimensional, or two-dimensional material to increase the critical temperature of the hydride at a given pressure (or lower the required pressure for a given temperature) at which the hydride exhibits superconductivity.

In various embodiments, any one of the hydrides described herein can be fabricated as a quasi-one-dimensional wire, tube, or ribbon (e.g., with two dimensions less than approximately 100 nanometers) or as a quasi-one-dimensional dot (e.g., with three dimensions less than approximately 100 nanometers) to increase the critical temperature of the hydride (and/or lower the required pressure for a given temperature) at which the hydride exhibits superconductivity.

In some embodiments, a superconducting system may include any one or more of the hydrides described herein, fabricated according to any one of the fabrication approaches described herein, immersed in a liquid to facilitate the cooling thereof to temperatures below the critical temperature and/or to facilitate the application of a pressure greater than a target or critical pressure to achieve superconductivity at a corresponding critical temperature.

In some embodiments, any one of the hydrides described herein may be subjected to a uniform hydrostatic pressure to facilitate superconductivity at a corresponding critical temperature. In other embodiments, any of the various hydrides described herein may be subjected to a uniaxial pressure along one or more specific crystallographic directions.

In some embodiments, a superconducting system may include one or more of the hydrides described herein, fabricated according to any of the fabrication configurations described herein, subjected to a magnetic field to increase the critical temperature and/or reduce the corresponding critical pressure at which the one or more hydrides exhibits superconductivity.

In some embodiments, electric gating is used to dope a hydride superconducting material to increase a critical temperature and/or lower a critical pressure at which the hydride superconducting material exhibits superconductivity. For example, electric gating may be accomplished using an electric field to transfer carriers from an external source (e.g., metal electrodes placed on the superconducting material) to the superconducting material to dope the superconducting material.

In some embodiments, a superconducting system may include one or more of the hydrides described herein, fabricated according to any of the fabrication configurations described herein, arranged for optical excitation with photon energies ranging from 1 meV to 100 eV that results in an increase in the critical temperature and/or reduction in the critical pressure at which the one or more hydrides exhibits superconductivity. In various embodiments, one or more of the hydrides described herein, fabricated according to any of the fabrication configurations described herein, may be integrated with a metamaterial, plasmonic structure, or phononic crystal to increase the critical temperature and/or reduce the critical pressure at which the one or more hydrides exhibits superconductivity.

Many existing computing devices and infrastructures may be used in combination with the presently described systems and methods. Some of the infrastructure that can be used with embodiments disclosed herein is already available, such as processors, microprocessors, microcontrollers, computer programming tools and techniques, digital storage media, and communication links.

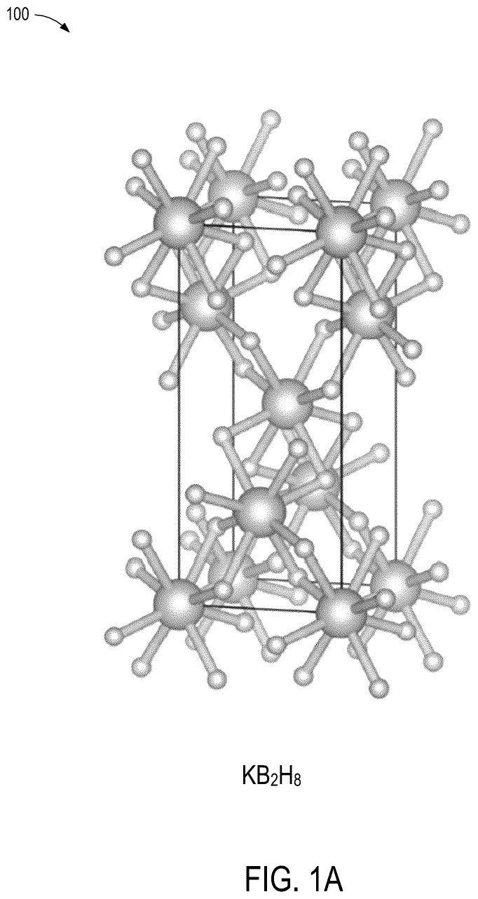

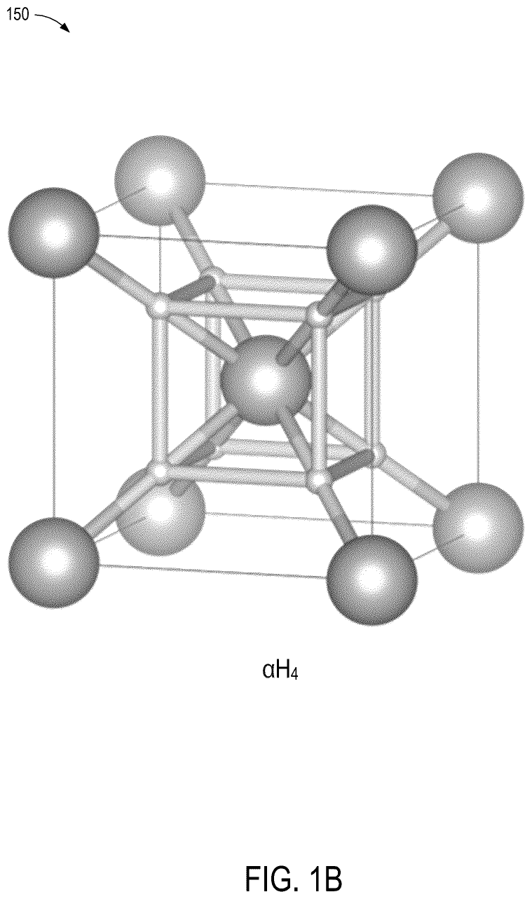

FIG. 1A illustrates an atomic configuration of a silane or silicon hydride (SiH₄) superconductor material 100, according to one embodiment. In one embodiment, a two-dimensional layer, thin film, or ribbon of SiH₄ is doped with nitrogen (N) to increase the critical temperature thereof. In another embodiment, a two-dimensional layer, thin film, or ribbon of SiH₄ is doped with boron (B) to increase the critical temperature thereof. In another embodiment, a two-dimensional layer, thin film, or ribbon of SiH₄ is doped with carbon (C) to increase the critical temperature thereof. In another embodiment, a two-dimensional layer, thin film, or ribbon of SiH₄ is doped with potassium (K) to increase the critical temperature thereof. In another embodiment, a two-dimensional layer, thin film, or ribbon of SiH₄ is doped with sodium (Na) to increase the critical temperature thereof.

In another embodiment, a two-dimensional layer, thin film, or ribbon of SiH₄ is doped with more than one type of dopant atom, including more than one of nitrogen (N), boron (B), carbon (C), potassium (K), and/or sodium (Na) to increase the critical temperature of the two-dimensional layer of SiH₄. For example, substitutional doping may be used to replace some atoms in the SiH₄ lattice structure with other atoms or molecules. For example, focused Ion beam deposition may be used, for example, to dope a bulk or two-dimensional hydride with potassium (K).

In some embodiments, a thin film of SiH₄ is fabricated to be less than ten structural unit cells thick (e.g., three-unit cells thick or five-unit cells thick). The thin film SiH₄ can have a higher critical temperature than a bulk form. Further, a monolayer (i.e., one-unit cell thick) of SiH₄ or a bilayer of SiH₄ (i.e., two-unit cells thick) can exhibit a higher critical temperature than the bulk form of SiH₄. In some embodiments, a ribbon of SiH₄ is used that has a higher critical temperature and/or lower critical pressure than a bulk form of SiH₄.

In some embodiments, a two-dimensional layer, thin film, or ribbon of SiH₄ is grown, fabricated, or otherwise deposited on a substrate material. The substrate material may, in some embodiments, exert a physical strain on the atomic structure of the doped or undoped SiH₄. In some embodiments, the substrate is selected to increase the critical temperature (or lower the critical pressure) at which the two-dimensional layer, thin film, or ribbon of SiH₄ exhibits superconductivity via electron transfer from the substrate and/or via bosonic excitations (e.g., phonons, excitons, etc.) in the substrate. The physical strain may be compressive and/or expansive (e.g., a tensile force) in one or both dimensions and/or with different amounts of force in each dimension.

FIG. 1B illustrates an atomic configuration of an αH₄ superconductor material 150, wherein α is an element selected from the periodic table, such as gold (Au), platinum (Pt), or silver (Ag), according to one embodiment. In the illustrated embodiment, the α atoms include the center atom and the eight outer corner atoms, while the hydrogen (H) atoms are represented by the eight small atoms forming the inner cube. A two-dimensional layer, thin film, or ribbon of αH₄ may be doped with nitrogen (N) to increase the critical temperature thereof. A two-dimensional layer, thin film, or ribbon of αH₄ may be doped with boron (B) to increase the critical temperature thereof. A two-dimensional layer, thin film, or ribbon of αH₄ may be doped with carbon (C) to increase the critical temperature thereof. A two-dimensional layer, thin film, or ribbon of αH₄ may be doped with potassium (K) to increase the critical temperature thereof. A two-dimensional layer, thin film, or ribbon of αH₄ may be doped with sodium (Na) to increase the critical temperature thereof.

A two-dimensional layer, thin film, or ribbon of αH₄ may be doped with more than one of nitrogen (N), boron (B), carbon (C), potassium (K), and/or sodium (Na) to increase the critical temperature thereof. For example, substitutional doping may be used to replace some atoms in the αH₄ lattice structure with other atoms or molecules. For example, focused Ion beam deposition may be used, for example, to dope a bulk or two-dimensional hydride with potassium (K).

In some embodiments, a two-dimensional layer, thin film, or ribbon of αH₄ is grown, fabricated, or otherwise deposited on a substrate material. The substrate material may, in some embodiments, exert a physical strain on the atomic structure of the doped or undoped αH₄. In some embodiments, the substrate is selected to increase the critical temperature (or lower the critical pressure) at which the two-dimensional layer, thin film, or ribbon of αH₄ exhibits superconductivity via electron transfer from the substrate and/or via bosonic excitations (e.g., phonons, excitons, etc.) in the substrate. The physical strain may be compressive and/or expansive (e.g., a tensile force) in one or both dimensions and/or with different amounts of force in each dimension.

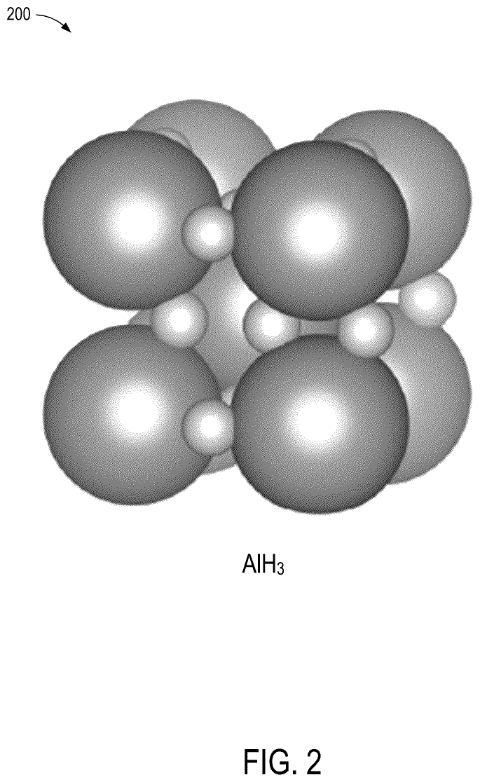

FIG. 2 illustrates an atomic configuration of an aluminum hydride (AlH₃) superconductor material 200, according to one embodiment. A two-dimensional layer, thin film, or ribbon of AlH₃ may be doped with nitrogen (N) to increase the critical temperature thereof. A two-dimensional layer, thin film, or ribbon of AlH₃ may be doped with boron (B) to increase the critical temperature thereof. A two-dimensional layer, thin film, or ribbon of AlH₃ may be doped with carbon (C) to increase the critical temperature thereof. A two-dimensional layer, thin film, or ribbon of AlH₃ may be doped with potassium (K) to increase the critical temperature thereof. A two-dimensional layer, thin film, or ribbon of AlH₃ may be doped with sodium (Na) to increase the critical temperature thereof.

A two-dimensional layer, thin film, or ribbon of AlH₃ may be doped with more than one of nitrogen (N), boron (B), carbon (C), potassium (K), and/or sodium (Na) to increase the critical temperature thereof. For example, substitutional doping may be used to replace some atoms in the AlH₃ lattice structure with other atoms or molecules. For example, focused Ion beam deposition may be used, for example, to dope a bulk or two-dimensional hydride with potassium (K).

In some embodiments, a two-dimensional layer, thin film, or ribbon of AlH₃ is grown, fabricated, or otherwise deposited on a substrate material. The substrate material may, in some embodiments, exert a physical strain on the atomic structure of the doped or undoped AlH₃. In some embodiments, the substrate is selected to increase the critical temperature (or lower the critical pressure) at which the two-dimensional layer, thin film, or ribbon of AlH₃ exhibits superconductivity via electron transfer from the substrate and/or via bosonic excitations (e.g., phonons, excitons, etc.) in the substrate. The physical strain may be compressive and/or expansive (e.g., a tensile force) in one or both dimensions and/or with different amounts of force in each dimension.

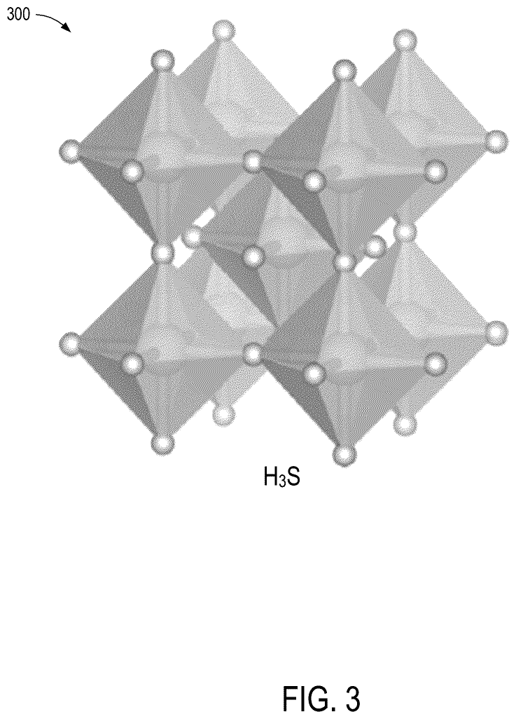

FIG. 3 illustrates an atomic configuration of a sulfur hydride (H₃S) superconductor material 300, according to one embodiment. A two-dimensional layer, thin film, or ribbon of H₃S may be doped with nitrogen (N) to increase the critical temperature thereof. A two-dimensional layer, thin film, or ribbon of H₃S may be doped with boron (B) to increase the critical temperature thereof. A two-dimensional layer, thin film, or ribbon of H₃S may be doped with carbon (C) to increase the critical temperature thereof. A two-dimensional layer, thin film, or ribbon of H₃S may be doped with potassium (K) to increase the critical temperature thereof. A two-dimensional layer, thin film, or ribbon of H₃S may be doped with sodium (Na) to increase the critical temperature thereof.

A two-dimensional layer, thin film, or ribbon of H₃S may be doped with more than one of nitrogen (N), boron (B), carbon (C), potassium (K), and/or sodium (Na) to increase the critical temperature thereof. For example, substitutional doping may be used to replace some atoms in the H₃S lattice structure with other atoms or molecules. For example, focused Ion beam deposition may be used, for example, to dope a bulk or two-dimensional hydride with potassium (K).

In some embodiments, a two-dimensional layer, thin film, or ribbon of H₃S is grown, fabricated, or otherwise deposited on a substrate material. The substrate material may, in some embodiments, exert a physical strain on the atomic structure of the doped or undoped H₃S. In some embodiments, the substrate is selected to increase the critical temperature (or lower the critical pressure) at which the two-dimensional layer, thin film, or ribbon of H₃S exhibits superconductivity via electron transfer from the substrate and/or via bosonic excitations (e.g., phonons, excitons, etc.) in the substrate. The physical strain may be compressive and/or expansive (e.g., a tensile force) in one or both dimensions and/or with different amounts of force in each dimension.

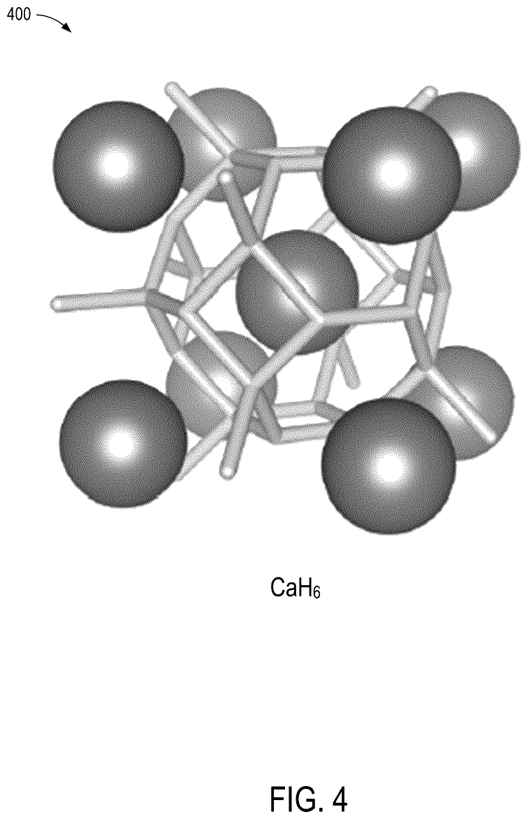

FIG. 4 illustrates an atomic configuration of a calcium hydride (CaH₆) superconductor material 400, according to one embodiment. A two-dimensional layer, thin film, or ribbon of CaH₆ may be doped with nitrogen (N) to increase the critical temperature thereof. A two-dimensional layer, thin film, or ribbon of CaH₆ may be doped with boron (B) to increase the critical temperature thereof. A two-dimensional layer, thin film, or ribbon of CaH₆ may be doped with carbon (C) to increase the critical temperature thereof. A two-dimensional layer, thin film, or ribbon of CaH₆ may be doped with potassium (K) to increase the critical temperature thereof. A two-dimensional layer, thin film, or ribbon of CaH₆ may be doped with sodium (Na) to increase the critical temperature thereof.

A two-dimensional layer, thin film, or ribbon of CaH₆ may be doped with more than one of nitrogen (N), boron (B), carbon (C), potassium (K), and/or sodium (Na) to increase the critical temperature thereof. For example, substitutional doping may be used to replace some atoms in the CaH₆ lattice structure with other atoms or molecules. For example, focused Ion beam deposition may be used, for example, to dope a bulk or two-dimensional hydride with potassium (K).

In some embodiments, a two-dimensional layer, thin film, or ribbon of CaH₆ is grown, fabricated, or otherwise deposited on a substrate material. The substrate material may, in some embodiments, exert a physical strain on the atomic structure of the doped or undoped CaH₆. In some embodiments, the substrate is selected to increase the critical temperature (or lower the critical pressure) at which the two-dimensional layer, thin film, or ribbon of CaH₆ exhibits superconductivity via electron transfer from the substrate and/or via bosonic excitations (e.g., phonons, excitons, etc.) in the substrate. The physical strain may be compressive and/or expansive (e.g., a tensile force) in one or both dimensions and/or with different amounts of force in each dimension.

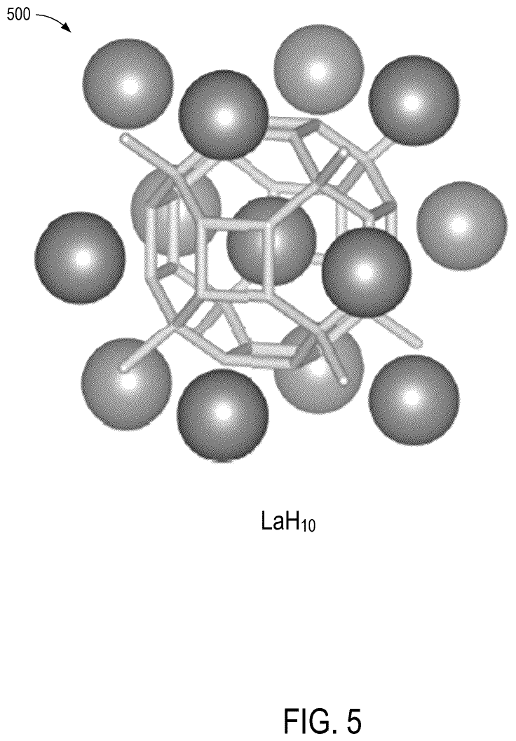

FIG. 5 illustrates an atomic configuration of a lanthanum decahydride (LaH₁₀) superconductor material 500, according to one embodiment. A two-dimensional layer, thin film, or ribbon of LaH₁₀ may be doped with nitrogen (N) to increase the critical temperature thereof. A two-dimensional layer, thin film, or ribbon of LaH₁₀ may be doped with boron (B) to increase the critical temperature thereof. A two-dimensional layer, thin film, or ribbon of LaH₁₀ may be doped with carbon (C) to increase the critical temperature thereof. A two-dimensional layer, thin film, or ribbon of LaH₁₀ may be doped with potassium (K) to increase the critical temperature thereof. A two-dimensional layer, thin film, or ribbon of LaH₁₀ may be doped with sodium (Na) to increase the critical temperature thereof.

A two-dimensional layer, thin film, or ribbon of LaH₁₀ may be doped with more than one of nitrogen (N), boron (B), carbon (C), potassium (K), and/or sodium (Na) to increase the critical temperature thereof. For example, substitutional doping may be used to replace some atoms in the LaH₁₀ lattice structure with other atoms or molecules. For example, focused Ion beam deposition may be used, for example, to dope a bulk or two-dimensional hydride with potassium (K).

In some embodiments, a two-dimensional layer, thin film, or ribbon of LaH₁₀ is grown, fabricated, or otherwise deposited on a substrate material. The substrate material may, in some embodiments, exert a physical strain on the atomic structure of the doped or undoped LaH₁₀. In some embodiments, the substrate is selected to increase the critical temperature (or lower the critical pressure) at which the two-dimensional layer, thin film, or ribbon of LaH₁₀ exhibits superconductivity via electron transfer from the substrate and/or via bosonic excitations (e.g., phonons, excitons, etc.) in the substrate. The physical strain may be compressive and/or expansive (e.g., a tensile force) in one or both dimensions and/or with different amounts of force in each dimension.

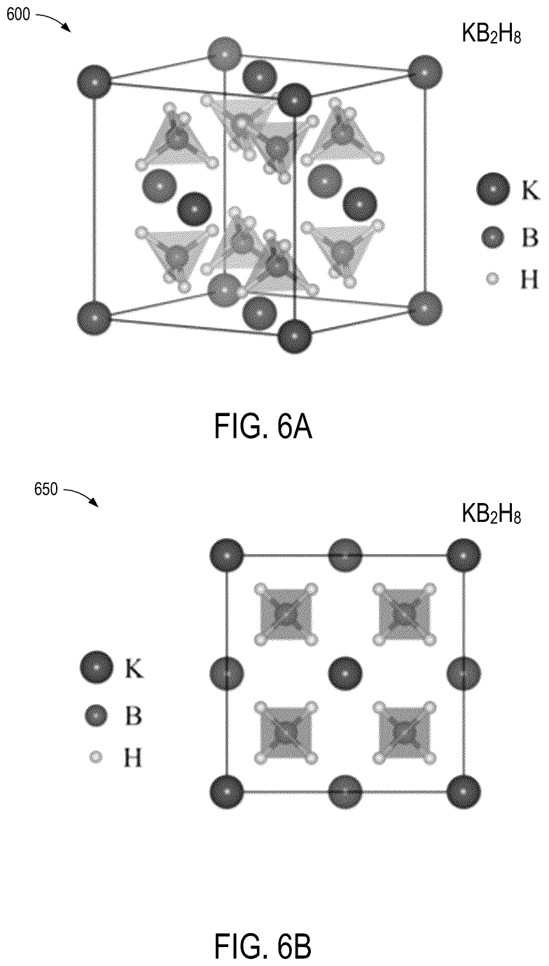

FIG. 6A illustrates a ball and stick diagram 600 of an atomic configuration of an example ternary hydride, KB₂H₈, according to one embodiment.

FIG. 6B illustrates a polyhedron diagram 650 of the atomic configuration of the ternary hydride, KB₂H₈, according to one embodiment. A two-dimensional layer, thin film, or ribbon of KB₂H₈ may be doped with nitrogen (N) to increase the critical temperature thereof. A two-dimensional layer, thin film, or ribbon of KB₂H₈ may be doped with boron (B) to increase the critical temperature thereof. A two-dimensional layer, thin film, or ribbon of KB₂H₈ may be doped with carbon (C) to increase the critical temperature thereof. A two-dimensional layer, thin film, or ribbon of KB₂H₈ may be doped with potassium (K) to increase the critical temperature thereof. A two-dimensional layer, thin film, or ribbon of KB₂H₈ may be doped with sodium (Na) to increase the critical temperature thereof.

A two-dimensional layer, thin film, or ribbon of KB₂H₈ may be doped with more than one of nitrogen (N), boron (B), carbon (C), potassium (K), and/or sodium (Na) to increase the critical temperature thereof. For example, substitutional doping may be used to replace some atoms in the KB₂H₈ lattice structure with other atoms or molecules. For example, focused Ion beam deposition may be used, for example, to dope a bulk or two-dimensional hydride with potassium (K).

In some embodiments, a two-dimensional layer, thin film, or ribbon of KB₂H₈ is grown, fabricated, or otherwise deposited on a substrate material. The substrate material may, in some embodiments, exert a physical strain on the atomic structure of the doped or undoped KB₂H₈. In some embodiments, the substrate is selected to increase the critical temperature (or lower the critical pressure) at which the two-dimensional layer, thin film, or ribbon of KB₂H₈ exhibits superconductivity via electron transfer from the substrate and/or via bosonic excitations (e.g., phonons, excitons, etc.) in the substrate. The physical strain may be compressive and/or expansive (e.g., a tensile force) in one or both dimensions and/or with different amounts of force in each dimension.

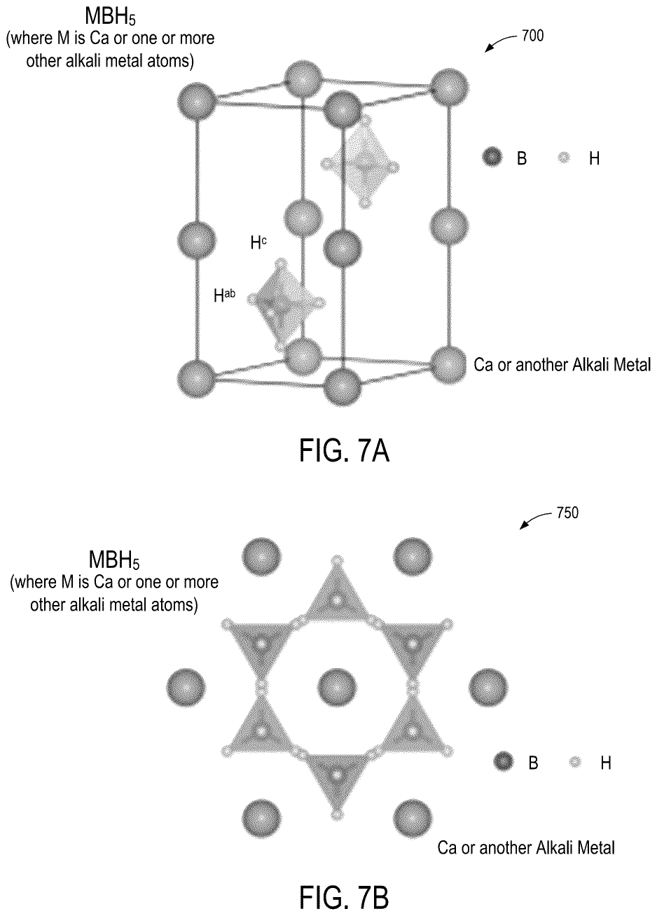

FIG. 7A illustrates a ball and stick diagram 700 of an atomic configuration of another example ternary hydride, CsBH₅, according to one embodiment.

FIG. 7B illustrates a polyhedron diagram 750 of the atomic configuration of the ternary hydride, CsBH₅, according to one embodiment. A two-dimensional layer, thin film, or ribbon of CsBH₅ may be doped with nitrogen (N) to increase the critical temperature thereof. A two-dimensional layer, thin film, or ribbon of CsBH₅ may be doped with boron (B) to increase the critical temperature thereof. A two-dimensional layer, thin film, or ribbon of CsBH₅ may be doped with carbon (C) to increase the critical temperature thereof. A two-dimensional layer, thin film, or ribbon of CsBH₅ may be doped with potassium (K) to increase the critical temperature thereof. A two-dimensional layer, thin film, or ribbon of CsBH₅ may be doped with sodium (Na) to increase the critical temperature thereof.

A two-dimensional layer, thin film, or ribbon of CsBH₅ may be doped with more than one of nitrogen (N), boron (B), carbon (C), potassium (K), and/or sodium (Na) to increase the critical temperature thereof. For example, substitutional doping may be used to replace some atoms in the CsBH₅ lattice structure with other atoms or molecules. For example, focused Ion beam deposition may be used, for example, to dope a bulk or two-dimensional hydride with potassium (K).

In some embodiments, a two-dimensional layer, thin film, or ribbon of CsBH₅ is grown, fabricated, or otherwise deposited on a substrate material. The substrate material may, in some embodiments, exert a physical strain on the atomic structure of the doped or undoped CsBH₅. In some embodiments, the substrate is selected to increase the critical temperature (or lower the critical pressure) at which the two-dimensional layer, thin film, or ribbon of CsBH₅ exhibits superconductivity via electron transfer from the substrate and/or via bosonic excitations (e.g., phonons, excitons, etc.) in the substrate. The physical strain may be compressive and/or expansive (e.g., a tensile force) in one or both dimensions and/or with different amounts of force in each dimension.

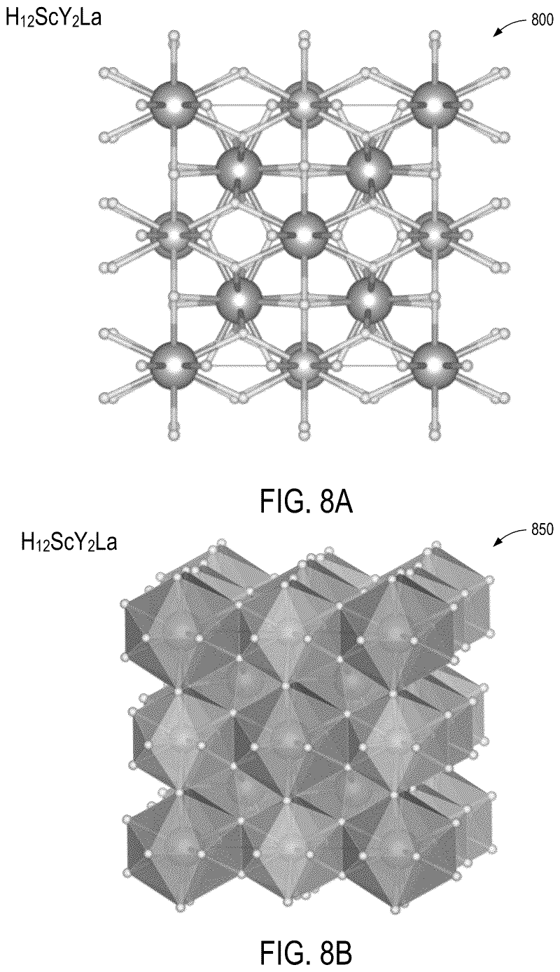

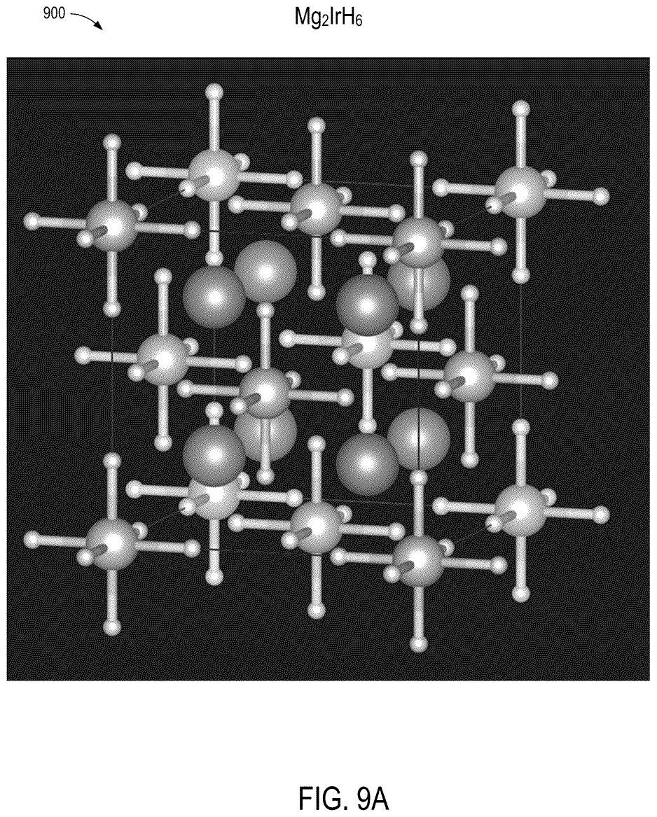

FIG. 8A illustrates a ball and stick diagram 800 of an atomic configuration of an example of a quaternary hydride, H₁₂ScY₂La, according to one embodiment.

FIG. 8B illustrates a polyhedron diagram 850 of the atomic configuration of the quaternary hydride, H₁₂ScY₂La, according to one embodiment. A two-dimensional layer, thin film, or ribbon of H₁₂ScY₂La may be doped with nitrogen (N) to increase the critical temperature thereof. A two-dimensional layer, thin film, or ribbon of H₁₂ScY₂La may be doped with boron (B) to increase the critical temperature thereof. A two-dimensional layer, thin film, or ribbon of H₁₂ScY₂La may be doped with carbon (C) to increase the critical temperature thereof. A two-dimensional layer, thin film, or ribbon of H₁₂ScY₂La may be doped with potassium (K) to increase the critical temperature thereof. A two-dimensional layer, thin film, or ribbon of H₁₂ScY₂La may be doped with sodium (Na) to increase the critical temperature thereof.

A two-dimensional layer, thin film, or ribbon of H₁₂ScY₂La may be doped with more than one of nitrogen (N), boron (B), carbon (C), potassium (K), and/or sodium (Na) to increase the critical temperature thereof. For example, substitutional doping may be used to replace some atoms in the H₁₂ScY₂La lattice structure with other atoms or molecules. For example, focused Ion beam deposition may be used, for example, to dope a bulk or two-dimensional hydride with potassium (K).

In some embodiments, a two-dimensional layer, thin film, or ribbon of H₁₂ScY₂La is grown, fabricated, or otherwise deposited on a substrate material. The substrate material may, in some embodiments, exert a physical strain on the atomic structure of the doped or undoped H₁₂ScY₂La. In some embodiments, the substrate is selected to increase the critical temperature (or lower the critical pressure) at which the two-dimensional layer, thin film, or ribbon of H₁₂ScY₂La exhibits superconductivity via electron transfer from the substrate and/or via bosonic excitations (e.g., phonons, excitons, etc.) in the substrate. The physical strain may be compressive and/or expansive (e.g., a tensile force) in one or both dimensions and/or with different amounts of force in each dimension.

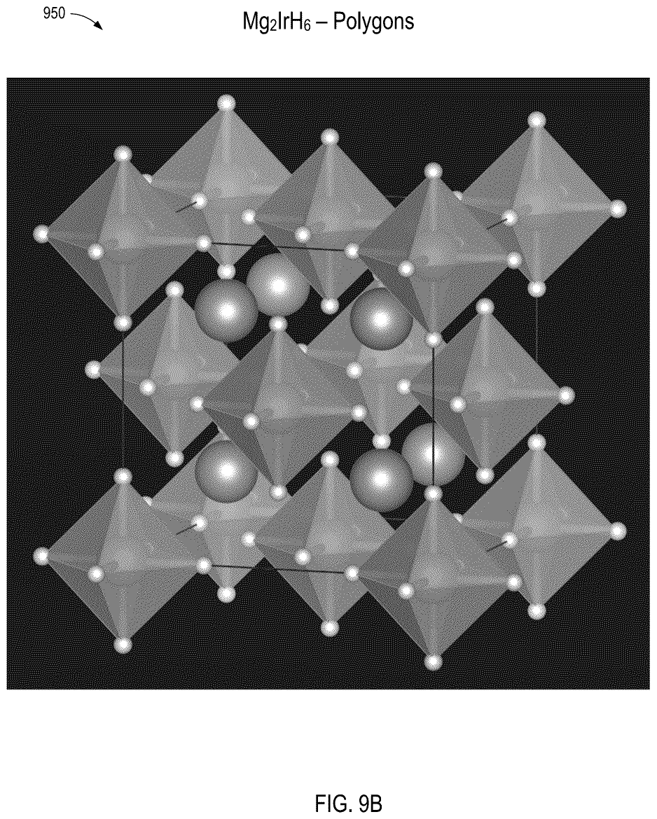

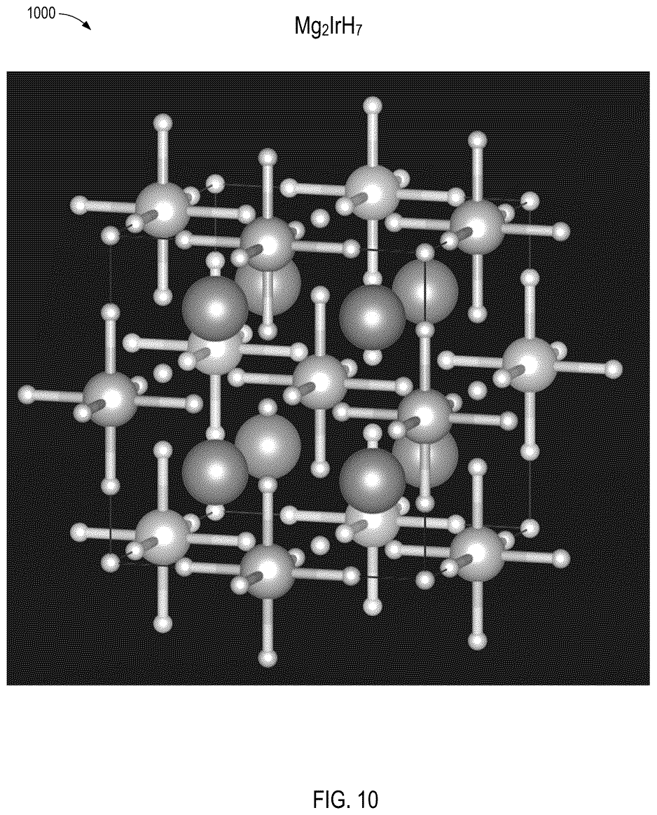

FIG. 9A illustrates ball and sick diagram 900 of an atomic configuration of a ternary hydride of the form α₂βH₆, specifically illustrating Mg₂IrH₆, according to one embodiment.

FIG. 9B illustrates polyhedron diagram 950 of the atomic configuration of a ternary hydride of the ternary hydride Mg₂IrH₆, according to one embodiment. A two-dimensional layer, thin film, or ribbon of Mg₂IrH₆ may be doped with nitrogen (N) to increase the critical temperature thereof. A two-dimensional layer, thin film, or ribbon of Mg₂IrH₆ may be doped with boron (B) to increase the critical temperature thereof. A two-dimensional layer, thin film, or ribbon of Mg₂IrH₆ may be doped with carbon (C) to increase the critical temperature thereof. A two-dimensional layer, thin film, or ribbon of Mg₂IrH₆ may be doped with potassium (K) to increase the critical temperature thereof. A two-dimensional layer, thin film, or ribbon of Mg₂IrH₆ may be doped with sodium (Na) to increase the critical temperature thereof.

A two-dimensional layer, thin film, or ribbon of Mg₂IrH₆ may be doped with more than one of nitrogen (N), boron (B), carbon (C), potassium (K), and/or sodium (Na) to increase the critical temperature thereof. For example, substitutional doping may be used to replace some atoms in the Mg₂IrH₆ lattice structure with other atoms or molecules. For example, focused Ion beam deposition may be used, for example, to dope a bulk or two-dimensional hydride with potassium (K).

In some embodiments, a two-dimensional layer, thin film, or ribbon of Mg₂IrH₆ is grown, fabricated, or otherwise deposited on a substrate material. The substrate material may, in some embodiments, exert a physical strain on the atomic structure of the doped or undoped Mg₂IrH₆. In some embodiments, the substrate is selected to increase the critical temperature (or lower the critical pressure) at which the two-dimensional layer, thin film, or ribbon of Mg₂IrH₆ exhibits superconductivity via electron transfer from the substrate and/or via bosonic excitations (e.g., phonons, excitons, etc.) in the substrate. The physical strain may be compressive and/or expansive (e.g., a tensile force) in one or both dimensions and/or with different amounts of force in each dimension.

FIG. 10 illustrates a ball and stick diagram 1000 of an atomic configuration of a ternary hydride of the form α₂βH₇, specifically illustrating Mg₂IrH₇, according to one embodiment. A two-dimensional layer, thin film, or ribbon of Mg₂IrH₇ may be doped with nitrogen (N) to increase the critical temperature thereof. A two-dimensional layer, thin film, or ribbon of Mg₂IrH₇ may be doped with boron (B) to increase the critical temperature thereof. A two-dimensional layer, thin film, or ribbon of Mg₂IrH₇ may be doped with carbon (C) to increase the critical temperature thereof. A two-dimensional layer, thin film, or ribbon of Mg₂IrH₇ may be doped with potassium (K) to increase the critical temperature thereof. A two-dimensional layer, thin film, or ribbon of Mg₂IrH₇ may be doped with sodium (Na) to increase the critical temperature thereof.

A two-dimensional layer, thin film, or ribbon of Mg₂IrH₇ may be doped with more than one of nitrogen (N), boron (B), carbon (C), potassium (K), and/or sodium (Na) to increase the critical temperature thereof. For example, substitutional doping may be used to replace some atoms in the Mg₂IrH₇ lattice structure with other atoms or molecules. For example, focused Ion beam deposition may be used, for example, to dope a bulk or two-dimensional hydride with potassium (K).

In some embodiments, a two-dimensional layer, thin film, or ribbon of Mg₂IrH₇ is grown, fabricated, or otherwise deposited on a substrate material. The substrate material may, in some embodiments, exert a physical strain on the atomic structure of the doped or undoped Mg₂IrH₇. In some embodiments, the substrate is selected to increase the critical temperature (or lower the critical pressure) at which the two-dimensional layer, thin film, or ribbon of Mg₂IrH₇ exhibits superconductivity via electron transfer from the substrate and/or via bosonic excitations (e.g., phonons, excitons, etc.) in the substrate. The physical strain may be compressive and/or expansive (e.g., a tensile force) in one or both dimensions and/or with different amounts of force in each dimension.

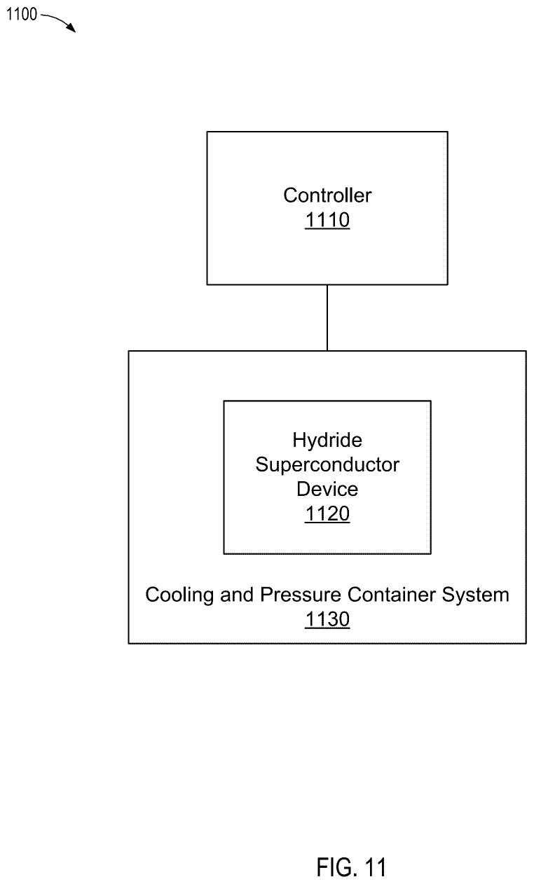

FIG. 11 illustrates a block diagram 1100 of a hydride superconducting device 1120 that is cooled and pressurized by a cooling and pressure container system 1130, according to one embodiment. A controller 1110, such as a microprocessor-based controller, may control the temperature and pressure within the cooling and pressure container system 1130. The hydride superconducting device 1120 may be embodied as any of the various hydride-based superconducting materials described herein.

In various embodiments, the hydride superconducting device 1120 is immersed within a liquid within the cooling and pressure container system 1130 to facilitate the cooling thereof to temperatures below the critical temperature and/or to facilitate the application of a pressure greater than a target or critical pressure to achieve superconductivity at a corresponding critical temperature.

In some embodiments, a non-uniform pressure is used to tune the critical temperature of the hydride superconducting device 1120. For example, a first pressure may be applied along a first dimension (e.g., axis), while a second pressure is applied along the other dimension (e.g., axis). As described herein, the cooling and pressure container system 1130 may apply a hydrostatic pressure to the hydride superconducting device 1120.

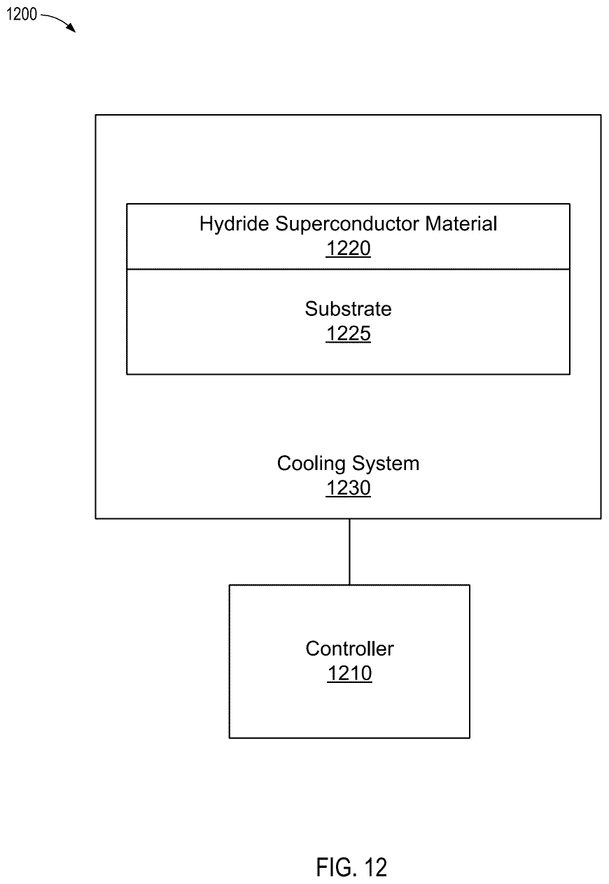

FIG. 12 illustrates a block diagram 1200 of a hydride superconducting material 1220 on a substrate 1225 that is cooled by a cooling system 1230, according to one embodiment. A controller 1210, such as a microprocessor-based controller, may control the temperature of the cooling system 1230. The hydride superconducting material 1220 may be embodied as any of the various hydride-based superconducting materials described herein.

In various embodiments, the hydride superconducting material 1220 may be embodied as a two-dimensional layer, thin film, or ribbon of any one or more of the binary, ternary, quaternary, etc. hydrides described herein. The hydride superconducting material 1220 may be fabricated (e.g., deposited, grown, etc.) on the substrate 1225. For example, the hydride superconducting material 1220 may be fabricated as a thin film or layers of thin films on top of a substrate 1225 such as, but not limited to, silicon (Si), germanium (Ge), another hydride, magnesium oxide (MgO), strontium titanate (SrTio₃), lanthanum strontium aluminum oxide (LSAO), lanthanum aluminate-strontium aluminum tantalate (LSAT), or graphene. In some embodiments, the thin film or layers of thin films may be fabricated on, for example, a van der Waals material. For example, a thin film binary, ternary, quaternary, etc. hydride may be fabricated on graphene or hexagonal boron nitride (hBN). As another example, a thin film binary, ternary, quaternary, etc. hydride may be fabricated on a transition metal dichalcogenide layer. Examples of suitable dichalcogenides include but are not limited to, MoS₂, NbSe₂, and WSe₂. Fabrication on various substrates and substances, such as those described above, are understood by those of skill in the art, including in the context of Geim et al., Van der Waals heterostructures, Nature 419, 499 (2013), which is hereby incorporated by reference to the extent allowed by law.

In some embodiments, the substrate 1225 is selected to exert a physical strain on the atomic structure of the hydride superconducting material 1220 (e.g., in a two-dimensional, thin film, or ribbon form) to increase the critical temperature at which the hydride superconducting material 1220 exhibits superconductivity (or lower the pressure at which the thin film hydride exhibits superconductivity for a given temperature). In some embodiments, the substrate is selected to increase the critical temperature (or lower the critical pressure) at which the hydride superconducting material 1220 exhibits superconductivity via electron transfer from the substrate and/or via bosonic excitations (e.g., phonons, excitons, etc.) in the substrate 1225.

In some embodiments, the substrate 1225 may exert a compressive force along only one dimension of the hydride superconducting material 1220 in two-dimensional, thin film, or ribbon form. In some embodiments, the substrate 1225 may exert an expansive force along only one dimension of the hydride superconducting material 1220 in two-dimensional, thin film, or ribbon form. In some embodiments, the substrate 1225 may exert a physical strain (compressive or expansive force) along multiple dimensions of the hydride superconducting material 1220 in two-dimensional, thin film, or ribbon form. In various embodiments, the physical strain may be stronger along a first dimension and weaker along a second dimension. In some embodiments, the physical strain may include a compressive force along one dimension and an expansive force along a second dimension.

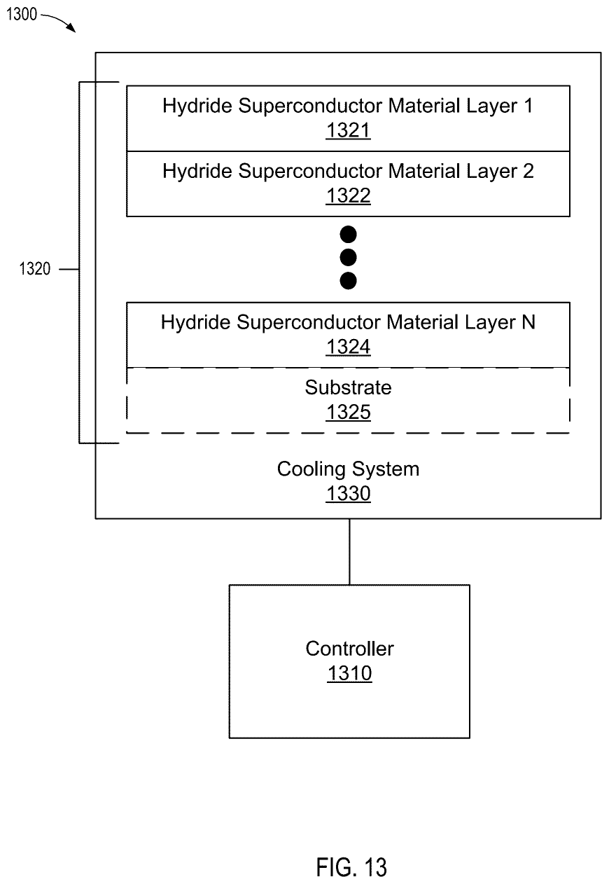

FIG. 13 illustrates a hydride superconducting superlattice 1320 on an optional substrate 1325 that is cooled by a cooling system 1330, according to one embodiment. A controller 1310, such as a microprocessor-based controller, may control the temperature of the cooling system 1330. The cooling system 1330 may also, in some embodiments, operate to control a pressure of a container within which the hydride superconducting superlattice 1320 is housed and/or a pressure on an encapsulated hydride superconducting superlattice 1320. The hydride superconducting superlattice 1320 may comprise a plurality of hydride layers of various types described herein. For example, a hydride superconducting superlattice 1320 may include a first layer 1321 formed as a thin film, two-dimensional layer, or ribbon of a first hydride superconducting material. The second layer 1322 of the hydride superconducting superlattice 1320 may be formed as a thin film, two-dimensional layer, or ribbon of a second hydride superconducting material. Any number of layers of different (or the same, e.g., alternating) hydride superconducting materials may be used to form the hydride superconducting superlattice 1320, as represented by the Nth layer 1324 of a thin film, two-dimensional layer, or ribbon of a hydride superconducting material. The hydride superconducting superlattice 1320 may, optionally, be formed on a substrate 1325 that may impart a physical strain along one, two, or three dimensions of the hydride superconducting superlattice 1320.

According to one embodiment, the hydride superconducting superlattice 1320 includes at least two layers of different hydride superconducting materials. In some embodiments, one or more of the hydride superconducting materials may be doped, as described herein. The layers may, for example, include doped or undoped layers of one or more of SiH₄, AlH₃, H₃S, CaH₆, LaH₁₀, KB₂H₈, CsBH₅, H₁₂ScY₂La, and/or one or more ternary hydrides in the form of α₂βH₆ (e.g., Mg₂IrH₆ or α₂βH₇).

The embodiments of the systems and methods provided within this disclosure are not intended to limit the scope of the disclosure but are merely representative of possible embodiments. In addition, the steps of a method do not necessarily need to be executed in any specific order, or even sequentially, nor do the steps need to be executed only once. In some instances, well-known structures, materials, or operations are not shown or described in detail in order to avoid obscuring aspects of this disclosure. This disclosure is to be regarded in an illustrative rather than a restrictive sense and encompasses at least the following claims.

1. A superconducting system, comprising:
a hydride superconducting lattice comprising at least:
a first layer with a first thin film hydride having a first composition, and
a second layer with a second thin film hydride having a second composition that is different from the first composition,
wherein at least one of the first thin film hydride and the second thin film hydride is doped with a dopant material;
a substrate to impart a physical strain along at least one dimension of the hydride superconducting lattice; and
a cooling system to cool the hydride superconducting superlattice below a critical temperature at which the hydride superconducting superlattice exhibits superconductivity.

2. A device, comprising:
a hydride superconducting material that includes at least one hydride selected from a group of hydrides consisting of: αHₓ, αβHₓ, and αβγHₓ,
wherein each of α, β, and γis a different element in the periodic table or chemical functional group, and wherein x represents an integer number of hydrogen atoms in the hydride.

3. The device of claim 2, wherein the hydride consists of a ternary hydride taking the form of αβHₓ, in which αβ is one of: LaB, KB₂, MgC₂, Ba—(CH₄), RbB₂, CsB₂, AlN₂, GaN₂, MgN₂, LaBe, BaSi, SrSi, K2Re, and CsB.

4. The device of claim 3, wherein the ternary hydride consists of one of: LaBH₈, KB₂H₈, MgC₂H₈, Ba—(CH₄)₃, RbB₂H₈, CsB₂H₈, AlN₂H₈, GaN₂H₈, MgN₂H₈, LaBeH₈, BaSiH₈, SrSiH₈, K2ReH₉, and CsBH₅.

5. The device of claim 2, wherein the hydride consists of a ternary hydride taking the form of αβH₆.

6. The device of claim 5, wherein the ternary hydride consists of one of: Mg₂IrH₆, Mg₂PtH₆, Mg₂RhH₆, Al₂MnH₆, Al₂ReH₆, Na₂AgH₆, Ca₂AgH₆, Na₂ZnH₆, Na₂AuH₆, Sr₂AgH₆, BNa₂H₆, Na₂AlH₆, AgBa₂H₆, Na₂GaH₆, TcIn₂H₆, In₂ReH₆, Ca₂GaH₆, NaBa₂H₆, Ca₂CuH₆, Ca₂PdH₆, CuSr₂H₆, NiNb₂H₆, GaSr₂H₆, AgCs₂H₆, CuY₂H₆, Sr₂PdH₆, Lu₂IrH₆, Lu₂ReH₆, TcLu₂H₆, Rb₂AgH₆, K₂AuH₆.

7. The device of claim 2, wherein the hydride consists of a ternary hydride taking the form of αβH₇.

8. The device of claim 7, wherein the ternary hydride consists of one of: Mg₂IrH₇, Mg₂PtH₇, Mg₂RhH₇, Al₂MnH₇, Al₂ReH₇, Na₂AgH₇, Ca₂AgH₇, Na₂ZnH₇, Na₂AuH₇, Sr₂AgH₇, BNa₂H₇, Na₂AlH₇, AgBa₂H₇, Na₂GaH₇, TcIn₂H₇, In₂ReH₇, Ca₂GaH₇, NaBa₂H₇, Ca₂CuH₇, Ca₂PdH₇, CuSr₂H₇, NiNb₂H₇, GaSr₂H₇, AgCs₂H₇, CuY₂H₇, Sr₂PdH₇, Lu₂IrH₇, Lu₂ReH₇, TcLu₂H₇, Rb₂AgH₇, K₂AuH₇.

9. The device of claim 2, wherein the hydride comprises a binary hydride in the form of εH₉, wherein ε is an element in the periodic table.

10. The device of claim 9, wherein the binary hydride comprises YH₉.

11. The device of claim 2, wherein the hydride comprises a hydride superconducting material in the form of a quaternary hydride taking the form of αβγHₓ.

12. The device of claim 11, wherein the quaternary hydride comprises at least one of H₁₂ScY₂Sr, H₁₂ScY₂La, H₁₂TiNi₃Ba, and H₁₂ScY₂Ca.

13. The device of claim 2, wherein the hydride superconducting material comprises:
a binary hydride superconducting material that includes at least one hydride selected from a group of hydrides consisting of: αH₄, βH₃, γH₆, and δH₁₀,
wherein each of α, β, γ, and δ is an element in the periodic table.

14-17. (canceled)

18. The device of claim 13, wherein the hydride superconducting material comprises δH₁₀ and the element δ is lanthanum, such that the hydride comprises LaH₁₀.

19. The device of claim 2, further including:
a cooling subsystem to cool the hydride superconducting material to a temperature below a critical temperature at which the hydride superconducting material exhibits superconductivity; and
a pressurization subsystem to pressurize the hydride superconducting material to a pressure above a critical pressure at which the hydride superconducting material exhibits superconductivity at the critical temperature.

20. The device of claim 2, wherein the hydride superconducting material is doped with a dopant to at least one of:
increase a critical temperature at which the hydride superconducting material exhibits superconductivity, and
lower a critical pressure at which the hydride superconducting material exhibits superconductivity.

21. The device of claim 20, wherein the dopant comprises nitrogen (N), boron (B), carbon (C), potassium (K), and sodium (Na).

22. The device of claim 2, wherein the hydride superconducting material is fabricated as a thin film that is less than one (1) micron thick.

23. The device of claim 2, wherein the hydride superconducting material is fabricated as a thin film that is between three (3)- and ten (10)-unit cells thick.

24-25. (canceled)

26. The device of claim 2, wherein the hydride superconducting material is fabricated on a substrate.

27. The device of claim 26, wherein the substrate comprises at least one of: silicon (Si), germanium (Ge), another hydride, magnesium oxide (MgO), strontium titanate (SrTio₃), lanthanum strontium aluminum oxide (LSAO), lanthanum aluminate-strontium aluminum tantalate (LSAT), and graphene.

28. The device of claim 26, wherein the substrate is selected to exert structural strain on the hydride superconducting material to at least one of:
increase a critical temperature at which the hydride superconducting material exhibits superconductivity, or
lower a critical pressure at which the hydride superconducting material exhibits superconductivity.

29. The device of claim 26, wherein the substrate is selected to transfer electrons to the hydride superconducting material to at least one of:
increase a critical temperature at which the hydride superconducting material exhibits superconductivity, or
lower a critical pressure at which the hydride superconducting material exhibits superconductivity.

30. The device of claim 26, wherein the substrate is selected to provide bosonic excitations for interaction with the hydride superconducting material to at least one of:
increase a critical temperature at which the hydride superconducting material exhibits superconductivity, or
lower a critical pressure at which the hydride superconducting material exhibits superconductivity.

31-34. (canceled)

35. The device of claim 2, wherein the hydride superconducting material comprises a superlattice structure having multiple thin layers of hydrides with different compositions.

36. The device of claim 35, wherein the hydride superconducting material comprises a superlattice structure having a repeating sequence of thin layers of hydrides, wherein at least two of the thin layers of hydrides in the repeating sequence have different compositions.

37-42. (canceled)

43. The device of claim 2, further comprising a pressurization subsystem to pressurize the hydride superconducting material.
(Currently amended) The device of claim 43, wherein the pressurization subsystem is configured to pressurize the hydride superconducting material along one or more axes.

45. The device of claim 43, wherein the pressurization subsystem is configured to pressurize the hydride superconducting material with a first pressure along a first axis and a second pressure along a second axis, wherein the first pressure and the second pressure are different.

46-50. (canceled)

51. The device of claim 2, wherein the hydride superconducting material further includes a clathrate boron from the group consisting of MgB₇, KB₇, La(BN)₅, Y(BN)₅, Al₂(BN)₆, and Al(BN)₆.

52-54. (canceled)

55. A device, comprising:
a hydride superconducting material in the form of αβHₓ, where each of α and β is a different element in the periodic table or chemical functional group, and x represents an integer number of hydrogen atoms in the hydride.

56. The device of claim 55, wherein α comprises one of Al, B, Ba, Be, C, Cs, Ga, K, La, Mg, N, Rb, Re, Si, and Sr and β comprises a different one of: Al, B, Ba, Be, C, Cs, Ga, K, La, Mg, N, Rb, Re, Si, and Sr.

57-58. (canceled)
